(19) United States
(12) Patent Application Publication
(10) Pub. No.: US 2019/0088812 A1
(43) Pub. Date: Mar. 21, 2019

(54) PHOTODETECTION ELEMENT, PHOTODETECTOR AND LASER IMAGING DETECTION AND RANGING APPARATUS

(71) Applicant: Kabushiki Kaisha Toshiba, Minato-ku (JP)

(72) Inventors: Yuki NOBUSA, Yokohama (JP); Kazuhiro SUZUKI, Meguro (JP)

(73) Assignee: Kabushiki Kaisha Toshiba, Minato-ku (JP)

(21) Appl. No.: 15/909,686

(22) Filed: Mar. 1, 2018

(30) Foreign Application Priority Data
Sep. 15, 2017 (JP) 2017-178191

(51) Int. Cl. H01L 31/103; H01L 31/02; H01L 31/107; H01S 5/026; G01C 3/08; G01S 17/89; H01L 27/144; H01L 27/146

(52) U.S. Cl. CPC H01L 31/103; H01L 31/02027; H01L 31/107; H01L 27/14629; G01C 3/08; G01S 17/89; H01L 27/1446; H01S 5/0262

(57) ABSTRACT

A photodetection element includes a first semiconductor layer; and a second semiconductor layer stacked on the first layer and converting light into electric charges; wherein the first semiconductor layer has a thickness of 5 μm or less.

### CROSS-REFERENCE TO RELATED APPLICATIONS

This application is based upon and claims the benefit of priority from the prior Japanese Patent Application No. 2017-178191, filed on Sep. 15, 2017, the entire contents of which are incorporated herein by reference

### FIELD

Embodiments described herein relate generally to a photodetection element, a photodetector and a laser imaging detection and ranging apparatus.

### BACK GROUND

A photodetection efficiency of a photodetection element is increased by applying a large voltage. However, generally, a dark current which is a cause of noise is also increased. When the dark current becomes large, much noise occurs, so that the element cannot be used as a photodetection element. However, the photodetection efficiency is decreased when the applied voltage is low, so there is a tradeoff between the noise reduction and the increased photodetection efficiency. Therefore, even when a large voltage is applied, a photodetection element with less noise is required.

### SUMMARY

The embodiments of invention are to provide a photodetection element with less noise even when a large voltage is applied.

In order to achieve the above object, a photodetection element according to an embodiment includes a first semiconductor layer and a second semiconductor layer that is provided on the first semiconductor layer and converts light into electric charges, wherein the first semiconductor layer has a thickness of 5 μm or less.

DESCRIPTION OF THE DRAWINGS

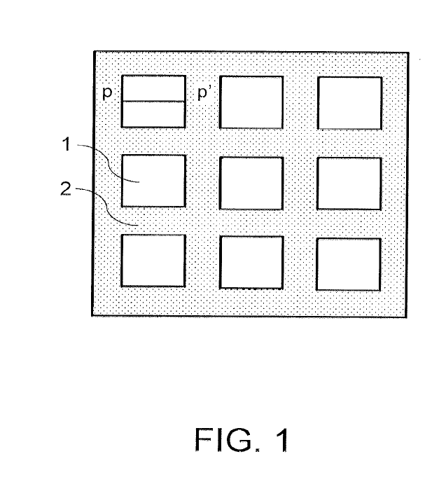

FIG. 1 is a diagram illustrating a photodetector according to a first embodiment;

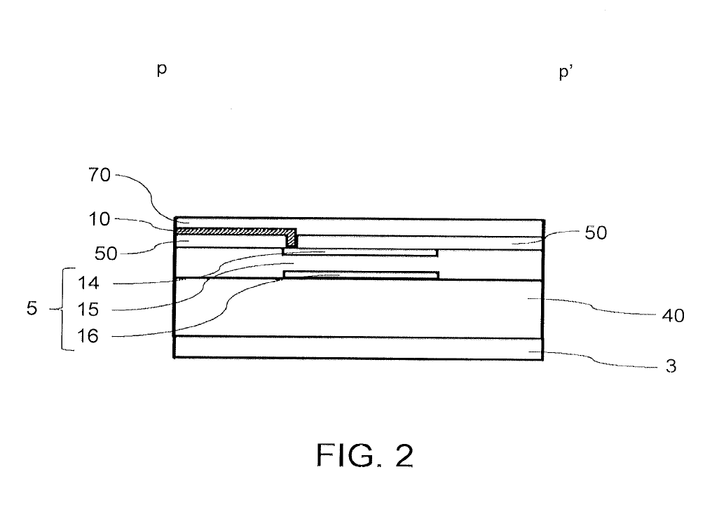

FIG. 2 is a diagram illustrating a p-p′ cross section of a photodetection element of the photodetector illustrated in FIG. 1;

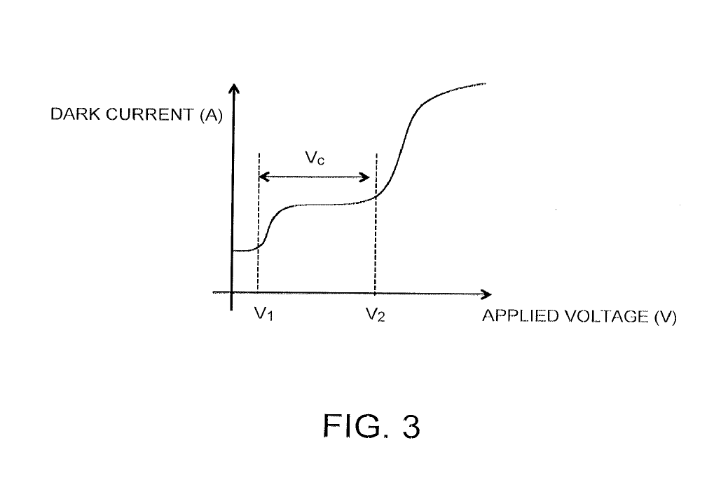

FIG. 3 is a graph illustrating a dark current when a voltage is applied to a photodetection element of the related art;

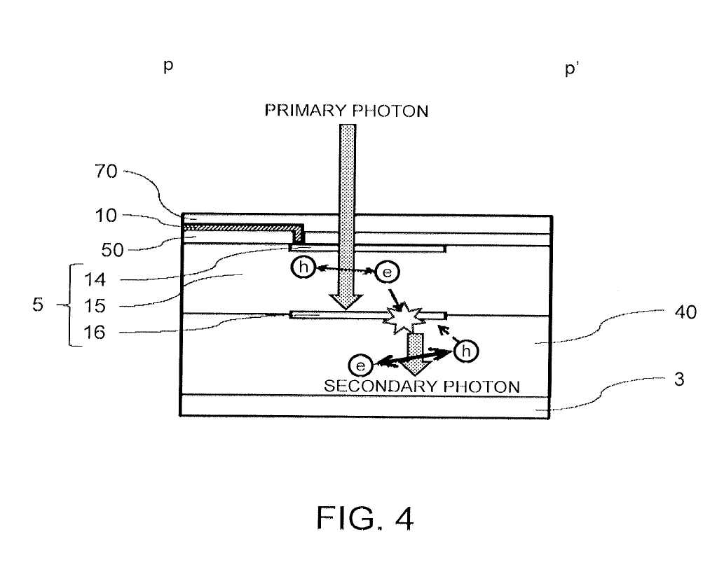

FIG. 4 is a diagram illustrating an example of a mechanism by which a dark current flows in the photodetection element of FIG. 2;

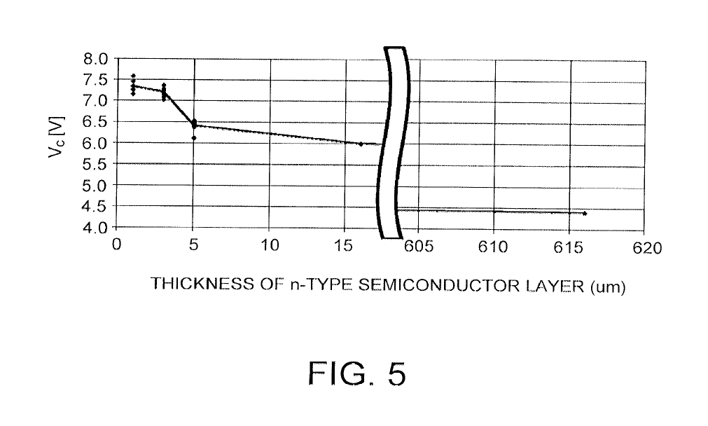

FIG. 5 is a graph illustrating a relationship between a thickness of a first semiconductor layer of the photodetection element and a voltage V_{c} applied to the photodetection element illustrated in FIG. 2;

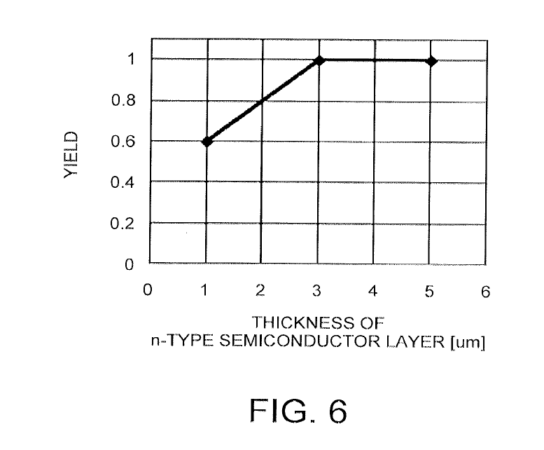

FIG. 6 is a graph illustrating a relationship between a thickness and a yield of the first semiconductor layer of the photodetection element illustrated in FIG. 2;

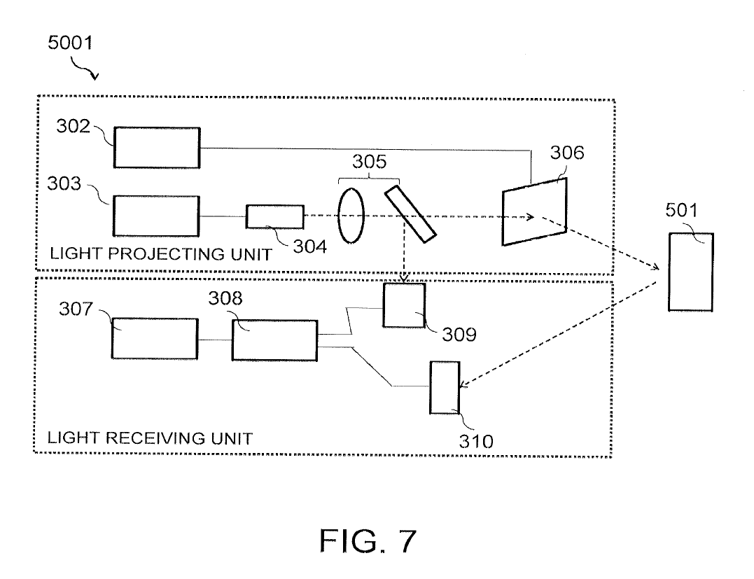

FIG. 7 is a diagram illustrating a LIDAR apparatus according to a third embodiment; and

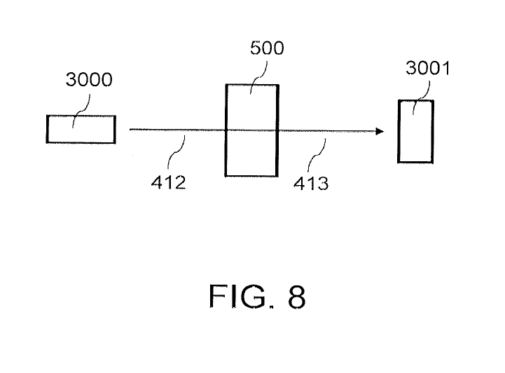

FIG. 8 is a diagram illustrating a measurement system of the LIDAR apparatus of FIG. 7.

### DETAILED DESCRIPTION

Hereinafter, embodiments of the invention will be described with reference to the drawings. Components denoted by the same reference numerals indicate corresponding ones. The drawings are schematic or conceptual, and a relationship between thickness and width of each portion, a ratio of sizes among portions, and the like are not necessarily the same as actual ones. In addition, even in the case of representing the same portions, the sizes and ratios of the portions may be different from each other depending on figures in the drawings.

### First Embodiment

FIG. 1 is a diagram illustrating a photodetector according to a first embodiment. This photodetector can convert incident light into electric charges and detect the light as an electric signal.

In FIG. 1, the photodetector includes a plurality of photodetection elements 1 arranged in an array shape and a non-photodetection area 2 provided between a plurality of the photodetection elements 1. Herein, the “upper” denotes the side on which light is incident.

The non-photodetection area 2 is an area in which incident light cannot be detected. The non-photodetection area 2 is an area for preventing adjacent photodetection elements 1 from interfering with each other and is an area in which wiring is provided for outputting electric signals converted by the photodetection elements 1 to a driving/reading unit (not illustrated).

The photodetection element 1 detects light by converting incident light into electric charges. For example, the photodetection element is an avalanche photodiode which operates in the Geiger mode.

FIG. 2 is a diagram illustrating a p-p′ cross section of a photodetection element 1 of the photodetector illustrated in FIG. 1.

The photodetection element 1 includes a first electrode 3, an n-type semiconductor layer 40 (sometimes, referred to as a first semiconductor layer), a p-type semiconductor layer 5 (sometimes, referred to as a second semiconductor layer), an insulating layer 50, a second electrode 10, and a protective layer 70 protecting the second electrode 10.

In the p-p′ cross section of FIG. 2, the n-type semiconductor layer 40 is stacked on the first electrode 3, and the p-type semiconductor layer 5 is stacked on the n-type semiconductor layer 40. The p-type semiconductor layer 5 includes a p− layer 15, a p+ layer 16 provided at least partially in the vicinity of the lower surface of the p− layer 15, and a p+ layer 14 provided at least partially in the vicinity of the upper surface of the p− layer 15. The insulating layer 50 is provided on the p-type semiconductor layer 5. The second electrode 10 is electrically connected to the p+ layer 14 in a portion of the insulating layer 50. In addition, the second electrode 10 is electrically connected to a wiring (not illustrated) of the non-photodetection area 2 on the upper surface of the insulating layer 50.

The protective layer 70 is provided so as to cover the upper surface of the insulating layer 50 and the upper surface of the second electrode 10.

The surface of the p+ layer 14 is a light-receiving surface. The second electrode 10 is provided between the insulating layer 50 and the protective layer 70. However, the p-p′ cross section is a cross section taken along a plane including the stacking direction and the plane direction.

The first electrode 3 is provided to apply a voltage to cause a potential difference to occur between the first electrode and the second electrode 10 (p+ layer 14). The material of the first electrode 3 is, for example, aluminum, an aluminum-containing material, or other metal materials combined with the material.

The n-type semiconductor layer 40 is preferably formed by doping a high-purity semiconductor (for example, silicon) with impurities (for example, phosphorus) at a high concentration of 1×10¹⁶/cm³ or more. As the concentration of the n-type semiconductor layer 40 becomes higher, the electric charge transfer is suppressed, and thus, the electric charges formed by the secondary photons can be more easily removed.

The p-type semiconductor layer 15 is formed by doping a high-purity semiconductor (for example, silicon) with impurities (for example, boron) at a concentration of 1×10¹⁵/cm³. The thickness of the p-type semiconductor layer 15 is preferably 2 μm or more and 4 μm or less.

The second electrode 10 is provided to transmit the photoelectrically converted electric charges to the non-photodetection area 2. The material of the second electrode 10 is, for example, aluminum, an aluminum-containing material, or other metal materials combined with the material.

The insulating layer 50 is provided so that the second electrode 10 is not short-circuited with the peripheral wiring. The material of the insulating layer 50 is, for example, a silicon oxide film or a silicon nitride film.

The protective layer 70 is provided to protect the second electrode 10 so as not to be short-circuited due to contact with the outside. The material of the protective layer 70 is, for example, a silicon oxide film or a silicon nitride film.

Next, a relationship between an applied voltage and a dark current between the first electrode 3 and the second electrode 10 will be described.

FIG. 3 is a graph illustrating the dark current when a voltage is applied to photodetection element 1. As illustrated in FIG. 3, in the rough shape of the graph, the dark current rapidly increases at the voltage V₁, and when the voltage is applied as it is, the dark current further increases at the voltage V₂. However, the voltage V₁ is the minimum value of the voltage necessary for the photodetection element 1 to perform photoelectric conversion, and the voltage V₂ is the value of the voltage at which the photoelectric conversion efficiency is the best in a case where the dark current is considered. When the range between the voltage V₁ and the voltage V₂ is set to be V_{c}, it is effective to apply a larger voltage in the voltage range V_{c} to the photodetection element 1 in terms of high light detection efficiency. When the voltage V₁ is set to be constant, the voltage range V_{c} increases as the voltage V₂ increases. Therefore, as the voltage range V_{c} increases, the applied voltage can also be increased, so that the photodetection element with high light detection efficiency and less noise can be realized.

The effect of reducing the thickness of the n-type semiconductor layer 40 in photodetection element will be described.

FIG. 4 is a diagram illustrating an example of s mechanism by which a dark current flows in the photodetection element 1 of FIG. 2.

As illustrated in FIG. 4, light (hereinafter, referred to as primary photons) is incident on the light-receiving surface. Holes (h) and electrons (e) are formed from the incident primary photons by the p-type semiconductor layer 5. The holes and the electrons (e) are collectively called electric charges. The electrons (e) formed by the p-type semiconductor layer 5 move to the vicinity of the pn junction, and the number of electrons increases due to the avalanche effect. While avalanche amplification is occurring, the secondary photons are emitted by processes such as bremsstrahlung and recombination, and then, the secondary photons are incident on the side closer to the n-type semiconductor layer 40 in FIG. 4. Holes (h) and electrons (e) are formed from the secondary photons by the n-type semiconductor layer 40. In the example of FIG. 4, the holes (h) reach the vicinity of the pn junction to generate a dark current due to the avalanche effect, which causes noise. Therefore, by reducing the thickness of the n-type semiconductor layer 40, which is the noise generation place, the formation of electric charges by the secondary photons can be reduced.

Next, a relationship between the thickness of the first semiconductor layer of the photodetection element and the voltage V_{c} applied to the photodetection element will be described.

FIG. 5 is a graph illustrating the relationship between the thickness of the first semiconductor layer in the photodetection element illustrated in FIG. 2 and the voltage V_{c} applied to the photodetection element.

Next, a relationship between the thickness of the n-type semiconductor layer 40 and the voltage range V_{c} applied between the first electrode 3 and the second electrode 10 will be described.

FIG. 5 is a graph illustrating the relationship between the thickness of the first semiconductor layer of the photodetection element illustrated in FIG. 2 and the voltage range V_{c} applied to the photodetection element.

As illustrated in FIG. 5, when the thickness of the n-type semiconductor layer 40 is reduced from 616 μm to 5 μm, the voltage range V_{c} is gradually increased. In addition, when the thickness of the n-type semiconductor layer 40 is reduced from 5 μm to 1 μm, the amount of increase in the voltage range V_{c} rapidly increases as compared with the amount of increase from 616 μm to 5 μm, and thus, when the thickness is 1 μm, the largest voltage range V_{c} can be obtained.

In a case where the thickness of the n-type semiconductor layer 40 is between 616 μm and 5 μm, since the n-type semiconductor layer 40 is thick, many electric charges are formed by the secondary photons. In the meantime, the distance at which the electric charges formed by the n-type semiconductor layer 40 reaches the pn junction is constant. Even if many electric charges are formed, a large portion of the electric charges generated in a portion deeper than 5 μm from the vicinity of the pn junction in the n-type semiconductor layer 40 disappears before the electric charges reach the vicinity of the pn junction. Therefore, the amount of increase in the voltage range V_{c} becomes small by reducing the thickness of the n-type semiconductor layer 40 to a range of from 616 μm to 5 μm. On the other hand, when the thickness of the n-type semiconductor layer 40 is set to be between 5 μm and 1 μm, the thickness of the n-type semiconductor layer 40 is reduced, and then, the electric charges formed in the n-type semiconductor layer 40 almost reaches the pn junction. However, since the thickness of the n-type semiconductor layer 40 is smaller than the above-described constant distance, the amount of the electric charges due to the secondary photons is reduced in the n-type semiconductor layer 40. Therefore, the thinner the n-type semiconductor layer 40, the larger the voltage range V_{c}.

Next, the yield when the photodetector is manufactured with the thickness of the n-type semiconductor layer 40 at 1, 3, and 5 μm will be described.

FIG. 6 is a graph illustrating the relationship between the thickness of the first semiconductor layer and the yield of the photodetection element illustrated in FIG. 2.

As illustrated in FIG. 6, when the thickness of the n-type semiconductor layer 40 was 3 and 5 μm, the yield was high. However, when the thickness was 1 μm, the yield was relatively low. Herein, the yield represents the proportion of samples with normal IV characteristics taken in the mounting evaluation. When the thickness of the n-type semiconductor layer 40 is 1 μm, the yield is low because it is considered that the semiconductor layer is so thin to be damaged during the mounting or is not normally formed at the film formation step. In terms of the yield, the thickness of the n-type semiconductor layer 40 is preferably 3 μm or more.

From the above results, the thickness of the n-type semiconductor layer 40 is more preferably 3 μm or more and 5 μm or less.

In the photodetector according to this embodiment, the number of electric charges formed by the secondary photons is suppressed by setting the thickness of the n-type semiconductor layer 40 to be between 3 μm and 5 μm. In addition, as the concentration of the n-type semiconductor layer 40 becomes high, the electric charges formed by the secondary photons can be more easily removed. Therefore, even if a large voltage is applied, it is possible to provide a photodetector with less noise.

Also, instead of the example of FIG. 2, the first semiconductor layer may be set to a p-type semiconductor layer, and the second semiconductor layer may be set to an n-type semiconductor layer.

### Second Embodiment

FIG. 7 is a diagram illustrating a LIDAR apparatus 5001 according to the second embodiment.

The LIDAR apparatus 5001 according to this embodiment can be applied to a long-distance subject detection system configured with a line light source, a lens, and the like. The LIDAR apparatus 5001 includes a light projecting unit which projects laser light to the object 501, a light receiving unit which receives the laser light from the object 501, and a time-of-flight (TOF) distance measurement device (not illustrated) which measures a time when the laser light reciprocates to return from the object 501 and reduces the time to a distance.

In the light projecting unit, the laser light oscillator 304 oscillates laser light. A driving circuit 303 drives the laser light oscillator 304. The optical system 305 extracts a portion of the laser light as a reference light and irradiates the object 501 with the other laser light through the mirror 306. The mirror controller 302 controls the mirror 306 to project the laser light onto the object 501. Herein, projecting denotes irradiating with light.

In the light receiving unit, the reference-light photodetector 309 detects the reference light emitted by the optical system 305. The photodetector 310 receives reflected light from the object 501. The distance measurement circuit 308 measures the distance to the object 501 based on the difference between the time when the reference-light photodetector 309 detects the reference light and the time when the photodetector 310 detects the reflected light. The image recognition system 307 recognizes the object 501 based on a result measured by the distance measurement circuit 308.

The LIDAR apparatus 5001 is a distance image sensing system employing a time-of-flight (TOF) distance measurement method which measures a time when the laser light reciprocates to return from the object 501 and reduces the time into a distance. The LIDAR apparatus 5001 is applied to an in-vehicle drive-assist system, remote sensing, or the like. When the photodetectors according to the first embodiment are used as the photodetector 310, the photodetector exhibits good sensitivity particularly in a near infrared region. Therefore, the LIDAR apparatus 5001 can be applied to a light source to a wavelength band invisible to a person. For example, the LIDAR apparatus 5001 can be used for detecting obstacles for vehicles.

FIG. 8 is a diagram illustrating the measurement system.

The measurement system includes at least a photodetector 3001 and a light source 3000. The light source 3000 of the measurement system emits light 412 to the object 501 to be measured. The photodetector 3001 detects the light 413 transmitted through, reflected by, or diffused by the object 501.

For example, when the photodetector 3001 is used as the photodetectors according to the first embodiment, a highly sensitive measurement system is embodied.

While several embodiments of the invention have been described above, the above-described embodiments have been presented by way of examples only, and the embodiments are not intended to limit the scope of the invention. The embodiments described herein may be embodied in a variety of other forms; furthermore, various omissions, substitutions, and changes in the form of the embodiments described herein may be made within the scope without departing from the spirit of the invention. The embodiments and modifications thereof are included in the scope and spirit of the invention and fall within the scope of the invention described in the claims and the equivalents thereof.

What is claimed is:

1. A photodetection element comprising:
a first semiconductor layer; and
a second semiconductor layer stacked on the first layer and converting light into electric charges;
wherein the first semiconductor layer has a thickness of 5 μm or less.

2. The photodetection element of claim 1,
wherein the first semiconductor layer formed by doping with impurities at a concentration of 1×10¹⁶/cm³ or more.

3. The photodetection element of claim 2,
wherein the first semiconductor layer has a thickness of 3 μm or more and 5 μm or less.

4. The photodetection element of claim 3,
wherein the second semiconductor layer has a thickness of 2 μm or more and 4 μm or less.

5. The photodetection element of claim 4,
wherein the photodetection element is an avalanche photodiode which operates in the Geiger mode.

6. A photodetector comprising:
a photodetection element including a first semiconductor layer and a second semiconductor layer stacked on the first layer and converting light into electric charges, wherein the first semiconductor layer has a thickness of 5 μm or less.
wherein the photodetection element is arranged in an array.

7. A LIDAR apparatus comprising:
a light source emitting light to an object; and
a photodetector including a photodetection element having a first semiconductor layer and a second semiconductor layer stacked on the first layer and converting light into electric charges, wherein the first semiconductor layer has a thickness of 5 μm or less and wherein the photodetection elements are arranged in an array;
wherein the photodetector detects incident light reflected by the object.
